(19) United States
(12) Patent Application Publication
(10) Pub. No.: US 2025/0019224 A1
(43) Pub. Date: Jan. 16, 2025

(54) MEMS DEVICE, MANUFACTURING METHOD THEREOF, AND ELECTRONIC APPARATUS

(71) Applicant: BOE TECHNOLOGY GROUP CO., LTD., Beijing (CN)

(72) Inventors: Jianxing LIU, Beijing (CN); Jingwen GUO, Beijing (CN); Qianhong WU, Beijing (CN); Chunxin LI, Beijing (CN); Zibo CAO, Beijing (CN); Jianyun ZHAO, Beijing (CN); Feng QU, Beijing (CN); Biqi LI, Beijing (CN)

(21) Appl. No.: 18/280,724

(22) PCT Filed: Oct. 27, 2022
(86) PCT No.: PCT/CN2022/127808

§ 371 Date: Sep. 7, 2023

(51) Int. Cl. B81B 3/00; B81C 1/00; H01P 1/18

(52) U.S. Cl. CPC B81B 3/0051; B81C 1/0038; B81B 2201/01; B81B 2203/0109; B81B 2203/0127; B81B 2203/04; B81C 2201/0104; B81C 2201/0105; B81C 2201/0132; B81C 2201/0133; B81C 2201/0176; H01P 1/18

(57) ABSTRACT

A MEMS device includes: a dielectric substrate; a driving electrode, first and second reference electrodes on the dielectric substrate; a first dielectric layer covering the driving electrode; and a membrane bridge on a side of the first dielectric layer away from the dielectric substrate, where a first gap is between the first reference electrode and the driving electrode; a second gap is between the second reference electrode and the driving electrode; and a thickness of a part of the first dielectric layer at each of the first and second gaps is greater than a thickness of the driving electrode; and/or, a second dielectric layer is on a side of a bridge deck of the membrane bridge close to the dielectric substrate, and an orthographic projection of the second dielectric layer on the dielectric substrate covers at least an orthographic projection of the driving electrode on the dielectric substrate.

### TECHNICAL FIELD

The present disclosure relates to the technical field of micro-electro-mechanical system, and in particular to a MEMS device, a manufacturing method thereof, and an electronic apparatus.

### BACKGROUND

A Micro-Electro-Mechanical System (MEMS) is a micro device or system that integrates a micro sensor, a micro actuator, a micro mechanical structure, a micro power source, a micro energy source, a signal processing and control circuit, an electronic integrated device with high performance, an interface, and communication. The MEMS is a revolutionary new technology, is widely applied to high-tech industries, and is a key technology related to science and technology development, economic prosperity and national defense safety of a country. With the rapid development of the information age, the MEMS device with high integration, miniaturization, multifunction, and low cost will bring huge economic value.

### SUMMARY

The present disclosure aims to solve at least one technical problem in the prior art, and provides a MEMS device, a manufacturing method thereof, and an electronic apparatus.

An embodiment of the present disclosure provides a MEMS device, including:
a dielectric substrate;
a driving electrode, a first reference electrode and a second reference electrode on the dielectric substrate, where the first reference electrode and the second reference electrode are on two sides of the driving electrode in an extending direction of the driving electrode, respectively;
a first dielectric layer covering the driving electrode on a side of the driving electrode away from the dielectric substrate; and
a membrane bridge on a side of the first dielectric layer away from the dielectric substrate, where two ends of an orthographic projection of the membrane bridge on the dielectric substrate overlap orthographic projections of the first reference electrode and the second reference electrode on the dielectric substrate, respectively; and the driving electrode is in a space enclosed by the membrane bridge and the dielectric substrate,
where a first gap is between the first reference electrode and the driving electrode; a second gap is between the second reference electrode and the driving electrode; and
a thickness of a part of the first dielectric layer at each of the first gap and the second gap is greater than a thickness of the driving electrode; and/or, a second dielectric layer is on a side of a bridge deck of the membrane bridge close to the dielectric substrate, and an orthographic projection of the second dielectric layer on the dielectric substrate covers at least an orthographic projection of the driving electrode on the dielectric substrate.

The thickness of the part of the first dielectric layer at each of the first gap and the second gap is greater than the thickness of the driving electrode, the first dielectric layer includes a first dielectric sub-layer and a second dielectric sub-layer sequentially arranged along a direction away from the dielectric substrate; and
the second dielectric sub-layer includes a first filling structure and a second filling structure; and the first filling structure and the second filling structure are in the first gap and the second gap, respectively.

The first dielectric sub-layer covers the first gap and the second gap, the first dielectric sub-layer forms a first groove part at the first gap, and the second dielectric sub-layer forms a second groove part at the second gap; the first filling structure fills the first groove part, and the second filling structure fills the second groove part.

A material of the second dielectric sub-layer includes resin adhesive.

The second dielectric layer is on the side of the bridge deck of the membrane bridge close to the dielectric substrate, and the second dielectric layer has a first convex part protruding toward the first dielectric layer.

The bridge deck of the membrane bridge has a second convex part protruding toward the first dielectric layer, the second convex part is in one-to-one correspondence with the first convex part, and the second convex part is embedded in the first convex part corresponding to the second convex part.

The thickness of the part of the first dielectric layer at each of the first gap and the second gap is greater than the thickness of the driving electrode, a surface of the first dielectric layer close to the second dielectric layer has a first concave part; and the first concave part and the first convex part are in one-to-one correspondence.

The first dielectric layer includes a first dielectric sub-layer and a second dielectric sub-layer sequentially arranged along a direction away from the dielectric substrate; and
the second dielectric sub-layer includes a first filling structure and a second filling structure; and the first filling structure and the second filling structure are in the first gap and the second gap, respectively.

The first filling structure and the second filling structure each have a first face in contact with the first sub-dielectric layer, a second face opposite to the dielectric substrate, and a first connection face connecting the first face and the second face; and the first connection face and the first dielectric sub-layer define the first concave part.

A material of the second dielectric sub-layer includes resin adhesive.

The thickness of the part of the first dielectric layer at each of the first gap and the second gap is greater than the thickness of the driving electrode, and the first dielectric layer includes a first dielectric sub-layer and a second dielectric sub-layer sequentially arranged along a direction close to the dielectric substrate; and
the second dielectric sub-layer includes a first filling structure and a second filling structure; and the first filling structure and the second filling structure are in the first gap and the second gap, respectively.

A material of the second dielectric sub-layer includes resin adhesive.

An embodiment of the present disclosure provides a method of manufacturing a MEMS device, including:
providing a dielectric substrate;
forming a driving electrode, a first reference electrode and a second reference electrode on the dielectric substrate; where the first reference electrode and the second reference electrode are on two sides of the driving electrode in an extending direction of the driving electrode, respectively;
forming a first dielectric layer on a side of the driving electrode, the first reference electrode and the second reference electrode, away from the dielectric substrate; and
forming a membrane bridge on a side of the first dielectric layer away from the dielectric substrate, where two ends of an orthographic projection of the membrane bridge on the dielectric substrate overlap orthographic projections of the first reference electrode and the second reference electrode on the dielectric substrate, respectively; and the driving electrode is in a space enclosed by the membrane bridge and the dielectric substrate,
where a first gap is between the first reference electrode and the driving electrode; a second gap is between the second reference electrode and the driving electrode; and a thickness of a part of the first dielectric layer at each of the first gap and the second gap is greater than a thickness of the driving electrode; and/or
the method further includes forming a second dielectric layer on a side of a bridge deck of the membrane bridge close to the dielectric substrate, where an orthographic projection of the second dielectric layer on the dielectric substrate covers at least an orthographic projection of the driving electrode on the dielectric substrate.

The thickness of the part of the first dielectric layer at each of the first gap and the second gap is greater than the thickness of the driving electrode, and forming the first dielectric layer includes:
sequentially forming a first dielectric sub-layer and a second dielectric sub-layer along a direction away from the dielectric substrate; where the second dielectric sub-layer includes a first filling structure and a second filling structure; and the first filling structure and the second filling structure are in the first gap and the second gap, respectively.

The method includes providing the second dielectric layer on the side of the bridge deck of the membrane bridge close to the dielectric substrate, and before forming the second dielectric layer, the method further includes:
forming a sacrificial layer on a surface of the first dielectric layer away from the dielectric substrate, where the sacrificial layer has a second concave part on a side of the sacrificial layer away from the dielectric substrate; and
the second dielectric layer is formed on a side of the sacrificial layer away from the dielectric substrate, and the second dielectric layer has a first convex part protruding toward the dielectric substrate; and the first convex part and the second concave part are arranged in one-to-one correspondence; and
the method further includes removing the sacrificial layer after forming the membrane bridge.

The thickness of the part of the first dielectric layer at each of the first gap and the second gap is greater than the thickness of the driving electrode, and the method includes providing the second dielectric layer at the side of the bridge deck of the membrane bridge close to the dielectric substrate,
forming the first dielectric layer includes:
sequentially forming a first dielectric sub-layer and a second dielectric sub-layer along a direction away from the dielectric substrate; where the second dielectric sub-layer includes a first filling structure and a second filling structure; and the first filling structure and the second filling structure are in the first gap and the second gap, respectively;
forming the second dielectric sub-layer includes:
forming a filling material in the first gap and the second gap, and annealing to form the first filling structure and the second filling structure; where the first filling structure and the second filling structure each have a first face in contact with the first sub-dielectric layer, a second face opposite to the dielectric substrate, and a first connection face connecting the first surface and the second face; and the first connection face and the first dielectric sub-layer define the first concave part;
after forming the second dielectric sub-layer, the method further includes:
forming a sacrificial layer on a surface of the first dielectric layer away from the dielectric substrate; where the sacrificial layer has a second concave part on a side of the sacrificial layer away from the dielectric substrate; and the second concave part and the first concave part are arranged in one-to-one correspondence; and
the second dielectric layer is formed on a side of the sacrificial layer away from the dielectric substrate, and the second dielectric layer has a first convex part protruding toward the dielectric substrate; and the first convex part and the second concave part are arranged in one-to-one correspondence; and
the method further includes removing the sacrificial layer after forming the membrane bridge.

The bridge deck of the membrane bridge is formed to have a second convex part protruding toward the first dielectric layer, and the second convex parts is arranged in one-to-one correspondence with the first convex part, and the second convex part is embedded in the first convex part corresponding to the second convex part.

The thickness of the part of the first dielectric layer at each of the first gap and the second gap is greater than the thickness of the driving electrode, and forming the first dielectric layer includes:
sequentially forming a second dielectric sub-layer and a first dielectric sub-layer along a direction away from the dielectric substrate; where the second dielectric sub-layer includes a first filling structure and a second filling structure; and the first filling structure and the second filling structure are in the first gap and the second gap, respectively;
forming the second dielectric sub-layer includes:
forming a second dielectric material sub-layer, where the second dielectric material layer protrudes out of the first gap and the second gap; and
heating the second dielectric material sub-layer, such that the second dielectric material sub-layer is reshaped to fill the first gap and the second gap, to form the first filling structure and the second filling structure.

The thickness of the part of the first dielectric layer at each of the first gap and the second gap is greater than the thickness of the driving electrode, forming the first dielectric layer includes:
sequentially forming a second dielectric sub-layer and a first dielectric sub-layer along a direction away from the dielectric substrate; the second dielectric sub-layer includes a first filling structure and a second filling structure; and the first filling structure and the second filling structure are in the first gap and the second gap, respectively; and
forming the second dielectric sub-layer includes:
forming a second dielectric material sub-layer, where the second dielectric material layer protrudes out of the first gap and the second gap; and
removing, through chemical mechanical polishing and grinding process, a part of the second dielectric material sub-layer protruding out of the first gap and the second gap, to form the first filling structure and the second filling structure filled in the first gap and the second gap, respectively.

An embodiment of the present disclosure provides an electronic apparatus, which includes any one of the MEMS devices described above.

### BRIEF DESCRIPTION OF DRAWINGS

FIG. 1 is a schematic diagram illustrating an off-state of an exemplary MEMS device as a switching device.

FIG. 2 is a schematic diagram illustrating an on-state of an exemplary MEMS device as a switching device.

FIG. 3 is a schematic diagram illustrating an off-state of another exemplary MEMS device as a switching device.

FIG. 4 is a schematic diagram illustrating an on-state of another exemplary MEMS device as a switching device.

FIG. 5 is a schematic diagram illustrating a structure of a MEMS device according to an embodiment of the present disclosure.

FIG. 6 is a schematic diagram illustrating a structure of a MEMS device in a first example of an embodiment of the present disclosure.

FIG. 7 is a flow chart of manufacturing the MEMS device shown in FIG. 6.

FIG. 8 is a schematic diagram illustrating a structure of a MEMS device in a second example of an embodiment of the present disclosure.

FIG. 9 is a flow chart of manufacturing the MEMS device shown in FIG. 8.

FIG. 10 is a schematic diagram illustrating a structure of a MEMS device in a third example of an embodiment of the present disclosure.

FIG. 11 is a flow chart of manufacturing the MEMS device shown in FIG. 10.

FIG. 12 is a schematic diagram illustrating a structure of a MEMS device in a fourth example of an embodiment of the present disclosure.

FIG. 13 is a flow chart of manufacturing the MEMS device shown in FIG. 12.

FIG. 14 is a schematic diagram illustrating a structure of a MEMS device in a fifth example of an embodiment of the present disclosure.

FIG. 15 is a flow chart of manufacturing the MEMS device shown in FIG. 14.

FIG. 16 is another flow chart of manufacturing the MEMS device shown in FIG. 14.

### DETAIL DESCRIPTION OF EMBODIMENTS

In order to enable one of ordinary skill in the art to better understand the technical solutions of the present disclosure, the present disclosure will be further described in detail below with reference to the accompanying drawings and specific embodiments.

Unless defined otherwise, technical or scientific terms used herein shall have the ordinary meaning as understood by one of ordinary skill in the art to which this disclosure belongs. The use of “first”, “second”, and the like in the present disclosure is not intended to indicate any order, quantity, or importance, but rather serves to distinguish one element from another. Also, the term “a”, “an”, “the” or the like does not denote a limitation of quantity, but rather denotes the presence of at least one. The word “including”, “includes”, or the like means that the element or item preceding the word includes the element or item listed after the word and its equivalent, but does not exclude other elements or items. The term “connected”, “coupled” or the like is not restricted to physical or mechanical connections, but may include electrical connections, whether direct or indirect. The terms “upper”, “lower”, “left”, “right”, and the like are used only to indicate relative positional relationships, and when the absolute position of the object being described is changed, the relative positional relationships may also be changed accordingly.

The Micro-Electro-Mechanical System (MEMS), also known as a micro electromechanical system, a micro system, a micro machine, or the like, refers to a high-tech device having a dimension of a few millimeters or less. The MEMS device in the embodiments of the present disclosure may be any MEMS-based device, which, for example, may be used for a radio frequency switch, probe detector, or a resonant beam. The MEMS device is also suitable for the design and application of other microstructures such as a circular diaphragm and a polygonal diaphragm used for, including but not limited to structures such as an accelerometer, an angular velocity meter, a miniature microphone, a micro-electro-mechanical interference display, a micro-electro-mechanical capacitive ultrasonic transducer, a micro mirror, or the like.

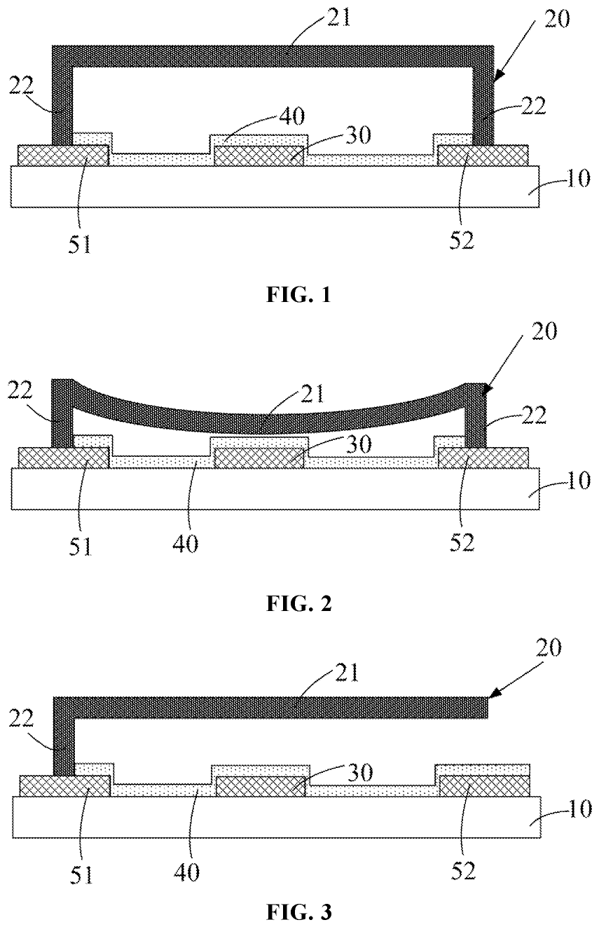

The MEMS device may be used as a switching device. FIG. 1 is a schematic diagram illustrating an off-state of an exemplary MEMS device as a switching device; and FIG. 2 is a schematic diagram illustrating an on-state of an exemplary MEMS device as a switching device. As shown in FIGS. 1 and 2, the MEMS device 100 includes: a dielectric substrate; a driving electrode 30, a first reference electrode and a second reference electrode arranged on the dielectric substrate 10; a first dielectric layer 40 covering the driving electrode 30; and a membrane bridge 20 arranged above the first dielectric layer 40, where the membrane bridge 20 includes a bridge deck 21 and two connecting arms 22 connected to two ends of the bridge deck 21, respectively. The bridge deck 21 of the membrane bridge 20 spans across the driving electrode with a certain distance from the first dielectric layer 40 on the driving electrode 30. That is, the membrane bridge 20 and the dielectric substrate 10 enclose a space. The first reference electrode 51 and the second reference electrode 52 are respectively located on two sides of the driving electrode 30 in an extending direction of the driving electrode 30, and the three electrodes may form a CPW (Co-Planar Waveguide) transmission line structure. The first reference electrode 21 and the second reference electrode 52 may be written with a reference ground signal.

Referring to FIG. 2, when a certain voltage is applied between the driving electrode 30 and the membrane bridge 20, the bridge deck 21 of the membrane bridge 20 will move toward the driving electrode 30 by the electrostatic force, thereby achieving the off-state of the switch. With reference to FIG. 1, when the voltage between the driving electrode 30 and the membrane bridge 20 is removed, the membrane bridge 20 will return to the original position, in which case the switch is turned on.

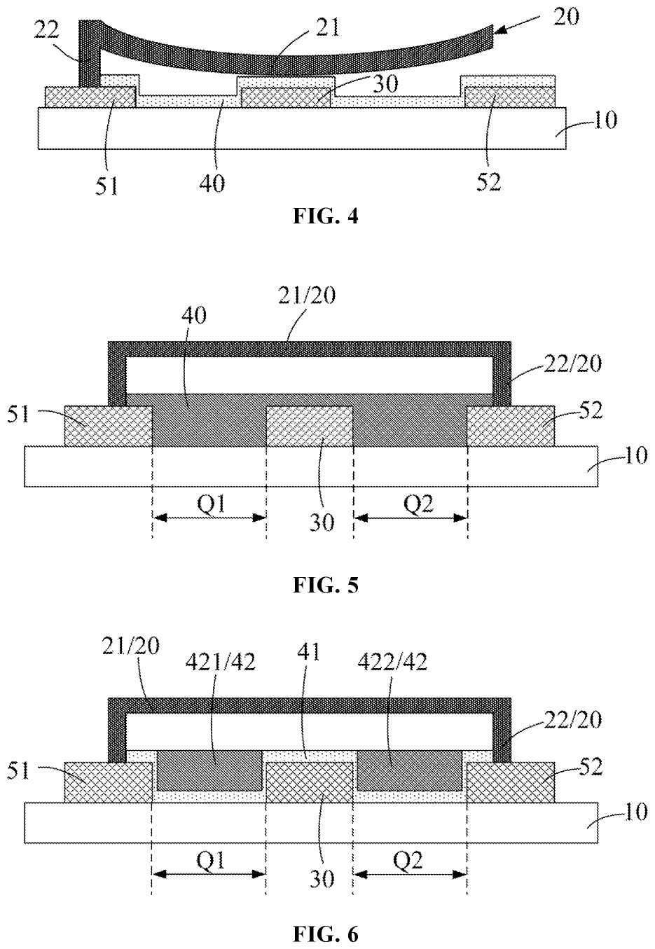

It should be noted that FIGS. 1 and 2 show a MEMS switch with a double-arm fixed beam structure, while the MEMS switch may alternatively include only one connecting arm 22, that is, the MEMS switch is of a cantilever beam structure. FIG. 3 is a schematic diagram illustrating an off-state of another exemplary MEMS device as a switching device; and FIG. 4 is a schematic diagram illustrating an on-state of another exemplary MEMS device as a switching device. As shown in FIGS. 3 and 4, the operation principle of this switch is the same as that of the MEMS switch of the two-arm fixed beam structure described above, and therefore, the description thereof will not be repeated.

The inventor finds that, in a case where the first dielectric layer covers the driving electrode, a thickness of the first dielectric layer covering a surface of the driving electrode away from the dielectric substrate, is greater than a thickness of the first dielectric layer covering a side surface of the driving electrode due to mechanical properties, that is, the thickness of the first dielectric layer on the side surface of the driving electrode is thinner, so that when the membrane bridge is pulled down, a point discharge is caused by a too close distance between the membrane bridge and the driving electrode below the membrane bridge, and there is a risk that the first dielectric layer on the side surface of the driving electrode is broken down to damage the device.

Based on the technical problem, the embodiments of the present disclosure provide the following MEMS device and a method of manufacturing the same. FIG. 5 is a schematic diagram illustrating a structure of a MEMS device according to an embodiment of the present disclosure. As shown in FIG. 5, the MEMS device according to an embodiment of the present disclosure includes: a dielectric substrate 10; and a driving electrode 30, a first reference electrode 51, a second reference electrode 52, a first dielectric layer 40, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The first dielectric layer 40 covers at least the driving electrode 30. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10.

The MEMS device of the present disclosure satisfies at least one of the following cases. In a first case, a thickness of the first dielectric layer 40 at the first gap Q1 and the second gap Q2 is greater than a thickness of the driving electrode 30, for example, the first dielectric layer 40 not only covers the driving electrode 30 but also fills the first gap Q1 and the second gap Q2, and a thickness of the first dielectric layer 40 covering the side surface of the driving electrode 30 is thicker, so that the risk that the first dielectric layer 40 on the side surface of the driving electrode 30 breaks down to cause device damage, due to point discharge caused by too close distance between the membrane bridge and the driving electrode 30 below when the membrane bridge is pulled down, can be effectively prevented. In a second case, a second dielectric layer 70 is arranged on a surface of the bridge deck 21 of the membrane bridge close to the dielectric substrate 10, and an orthographic projection of the second dielectric layer 70 on the dielectric substrate 10 covers at least an orthographic projection of the driving electrode 30 on the dielectric substrate 10, so that the risk that the first dielectric layer 40 on the side surface of the driving electrode 30 breaks down to cause device damage, due to point discharge caused by too close distance between the membrane bridge and the driving electrode 30 below when the membrane bridge is pulled down, can also be effectively prevented through the arrangement of the second dielectric layer 70.

In order to make the structure of the MEMS device according to the embodiment of the present disclosure clearer, the MEMS device according to the embodiment of the present disclosure is described in detail below with reference to a specific example and a manufacturing method thereof.

A first example is as follows. FIG. 6 is a schematic diagram illustrating a structure of a MEMS device in a second example of an embodiment of the present disclosure; as shown in FIG. 6, the MEMS device includes: a dielectric substrate 10; and a driving electrode 30, a first reference electrode 51, a second reference electrode 52, a first dielectric layer 40, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The first dielectric layer 40 includes a first dielectric sub-layer 41 and a second dielectric sub-layer 42 sequentially arranged along a direction away from the dielectric substrate 10. The first dielectric sub-layer 41 covers the driving electrode 30 on a side of the driving electrode 30 away from the dielectric substrate 10. The second dielectric sub-layer 42 includes a first filling structure 421 and a second filling structure 422, and the first filling structure 421 and the second filling structure 422 fill the first gap Q1 and the second gap Q2, respectively. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10.

In some examples, with continued reference to FIG. 6, the first dielectric sub-layer 41 covers the first gap Q1 and the second gap Q2, and forms a first groove part and a second groove part in the first gap Q1 and the second gap Q2, respectively, with the first groove part being filled by the first filling structure 421 and the second groove part being filled by the second filling structure 422. In order to ensure that a surface of the first dielectric layer 40 away from the dielectric substrate 10 is flat, a thickness of each of the first filling structure 421 and the second filling structure 422 is the same as a thickness of the driving electrode 30.

Furthermore, a material of the first dielectric sub-layer 41 may be silicon oxide. A material of the second dielectric sub-layer 42, that is, a material of the first filling structure 421 and the second filling structure 422, may be resin adhesive.

In some examples, a material of the driving electrode 30, the first reference electrode 51, and the second reference electrode 52 includes, but is not limited to, copper. The membrane bridge 20 may be formed by three layers of a laminated structure, where the three layers of the laminated structure are made of molybdenum, aluminum and molybdenum, respectively.

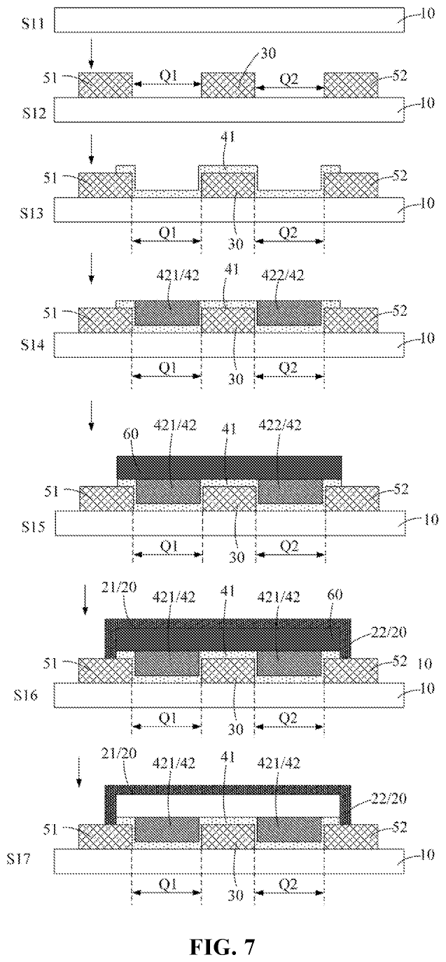

Next, a method of manufacturing a first exemplary MEMS device will be described. FIG. 7 is a flowchart of manufacturing the MEMS device shown in FIG. 6. As shown in FIG. 7, the manufacturing method may specifically include the following steps S11 to S17.

S11, providing the dielectric substrate 10.

In some examples, the dielectric substrate 10 may be a glass substrate, and in step S11, a glass substrate of 0.5 mm may be selected, and then the glass substrate is cleaned by a standard cleaning process.

S12, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S12 may include: forming a first conductive film through, including but not limited to, magnetron sputtering, then forming the driving electrode 30, the first reference electrode 51 and the second reference electrode 52, through coating a photoresist, exposing and developing the photoresist, and etching (for example, wet etching), and finally removing the remaining photoresist to complete the manufacturing of the driving electrode 30, the first reference electrode 51 and the second reference electrode 52.

S13, forming the first dielectric sub-layer 41 of the first dielectric layer 40 on a side of a layer, where the driving electrode 30, the first reference electrode 51 and the second reference electrode 52 are located, away from the dielectric substrate 10; where the first dielectric sub-layer 41 covers the driving electrode 30, and may further cover the first gap Q1 and the second gap Q2. In this case, the first sub dielectric layer 41 forms the first groove part and the second groove part located at the first gap Q1 and the second gap Q2, respectively.

In some examples, the first dielectric sub-layer 41 may be made of silicon oxide. In a case where the first dielectric sub-layer 41 is made of silicon oxide, the step S13 may include: forming the first dielectric sub-layer 41 of the first dielectric layer 40 on the side of the layer, where the driving electrode 30, the first reference electrode 51 and the second reference electrode 52 are located, away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that the first dielectric sub-layer 41 formed in FIG. 6 also covers a part of the first reference sub-electrode and a part of the second reference sub-electrode, so as to ensure that the thickness of the second dielectric sub-layer 42 formed in the first groove part and the second groove part is uniform.

S14, forming the second dielectric sub-layer 42 on a side of the first dielectric sub-layer 41 away from the dielectric substrate 10, where the second dielectric sub-layer 42 includes the first filling structure 421 filling the first groove part and the second filling structure 422 filling the second groove part.

In some examples, a material of the second dielectric sub-layer 42 includes, but is not limited to, resin adhesive. Taking the second dielectric sub-layer 42 made of resin adhesive as an example, step S14 may include: firstly, forming a filling material in both of the first groove part and the second groove part through a spin process, where an orthographic projection of the filling material on the dielectric substrate 10 covers orthographic projections of the first gap Q1 and the second gap Q2 on the dielectric substrate 10; and then heating the filling material, so that the filling material is reshaped to fill the first gap Q1 and the second gap Q2, to form the first filling structure 421 filling the first groove part and the second filling structure 422 filling the second groove part.

It should be noted that, the thicknesses of the first filling structure 421 and the second filling structure 422 are the same as the thickness of the driving electrode 30, and the control on the thickness of the first filling structure 421 and the second filling structure 422 can be realized by controlling the spin rate of the spin coating.

S15, forming a sacrificial layer 60 on a side of the first dielectric sub-layer 41 and the second dielectric sub-layer 42 away from the dielectric substrate 10.

In some examples, the sacrificial layer 60 may be made of silicon nitride, which is used because the first dielectric sub-layer 41 made of silicon oxide will not be damaged when the sacrificial layer 60 is removed subsequently. In a case where the sacrificial layer 60 is made of silicon nitride, the step S15 may include: forming the sacrificial layer 60 on the side of the first dielectric sub-layer 41 and the second dielectric sub-layer 42 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S16, forming the membrane bridge on a side of the sacrificial layer 60 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10.

In some examples, two connecting arms 22 of the membrane bridge are in contact with and electrically connected to first reference electrode 51 and second reference electrode 52, respectively. Step S16 may specifically include: forming a second conductive film through, but not limited to, magnetron sputtering, then forming a pattern including the membrane bridge, through coating a photoresist, exposing and developing the photoresist, and etching (for example, wet etching), and finally removing the photoresist, to complete the manufacturing of the membrane bridge.

S17, removing the sacrificial layer 60.

In some examples, step S17 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge, to complete the manufacturing of the MEMS device. The gas atmosphere is SF₆ gas.

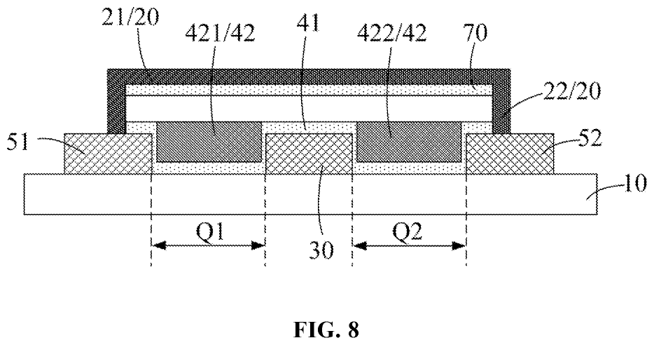

A second example is as follows. FIG. 8 is a schematic diagram illustrating a structure of a MEMS device in a second example of an embodiment of the present disclosure; as shown in FIG. 8, the MEMS device includes: a dielectric substrate 10; and a driving electrode 30, a first reference electrode 51, a second reference electrode 52, a first dielectric layer 40, a second dielectric layer 70, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The first dielectric layer 40 includes a first dielectric sub-layer 41 and a second dielectric sub-layer 42 sequentially arranged along a direction away from the dielectric substrate 10. The first dielectric sub-layer 41 covers the driving electrode 30 on a side of the driving electrode 30 of away from the dielectric substrate 10. The second dielectric sub-layer 42 includes a first filling structure 421 and a second filling structure 422, and the first filling structure 421 and the second filling structure 422 fill the first gap Q1 and the second gap Q2, respectively. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10. The second dielectric layer 70 is located on a surface of a bridge deck 21 of the membrane bridge close to the dielectric substrate 10, and an orthographic projection of the second dielectric layer 70 on the dielectric substrate 10 covers at least an orthographic projection of the first dielectric layer 40 on the dielectric substrate 10.

In some examples, with continued reference to FIG. 8, the first dielectric sub-layer 41 covers the first gap Q1 and the second gap Q2, and forms a first groove part and a second groove part in the first gap Q1 and the second gap Q2, respectively, with the first groove part being filled by the first filling structure 421 and the second groove part being filled by the second filling structure 422. In order to ensure that a surface of the first dielectric layer 40 away from the dielectric substrate 10 is flat, a thickness of the first filling structure 421 and the second filling structure 422 is the same as a thickness of the driving electrode 30.

Furthermore, a material of the first dielectric sub-layer 41 and the second dielectric sub-layer 70 may be silicon oxide. A material of the second dielectric sub-layer 42, that is, a material of the first filling structure 421 and the second filling structure 422, may be resin adhesive.

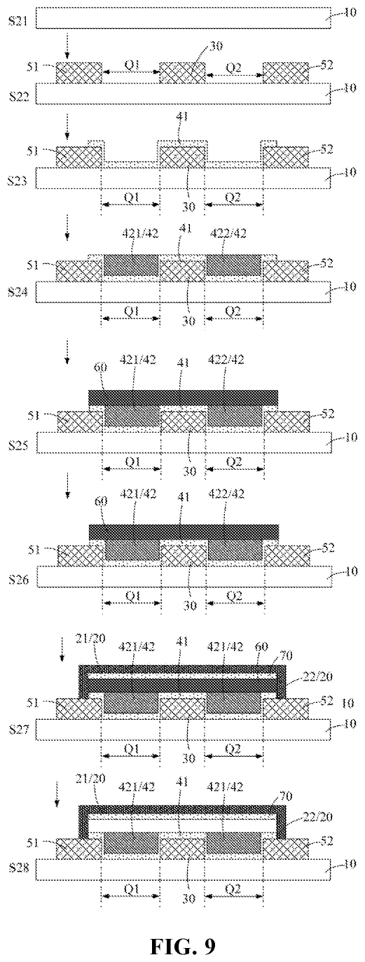

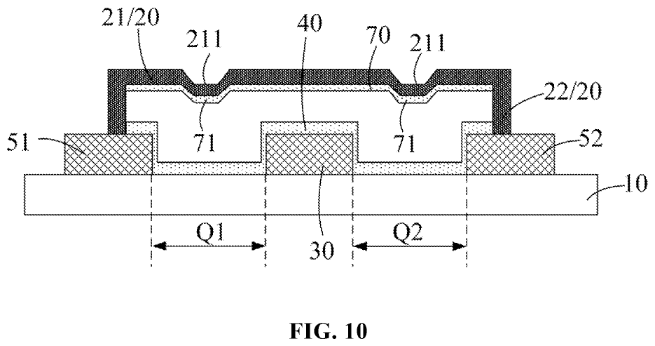

Next, a method of manufacturing a second exemplary MEMS device will be described. FIG. 9 is a flowchart of manufacturing the MEMS device shown in FIG. 8. As shown in FIG. 9, the manufacturing method may specifically include the following steps S21 to S28.

S21, providing the dielectric substrate 10.

In some examples, the dielectric substrate 10 may be a glass substrate, and in step S21, a glass substrate of 0.5 mm may be selected, and then the glass substrate is cleaned by a standard cleaning process.

S22, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S22 may include: forming a first conductive film through, including but not limited to, magnetron sputtering, then forming the driving electrode 30, the first reference electrode 51 and the second reference electrode 52, through coating a photoresist, exposing and developing the photoresist, and etching (for example, wet etching), and finally removing the remaining photoresist to complete the manufacturing of the driving electrode 30, the first reference electrode 51 and the second reference electrode 52.

S23, forming a first dielectric sub-layer 41 in the first dielectric layer 40 on a side of a layer, where the driving electrode 30, the first reference electrode 51 and the second reference electrode 52 are located, away from the dielectric substrate 10; where the first dielectric sub-layer 41 covers the driving electrode 30, and may further cover the first gap Q1 and the second gap Q2. In this case, the first sub dielectric layer 41 forms the first groove part and the second groove part located at the first gap Q1 and the second gap Q2, respectively.

In some examples, the first dielectric sub-layer 41 may be made of silicon oxide. In a case where the first dielectric sub-layer 41 is made of silicon oxide, the step S23 may include: forming the first dielectric sub-layer 41 of the first dielectric layer 40 on the side of the layer, where the driving electrode 30, the first reference electrode 51 and the second reference electrode 52 are located, away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that the first dielectric sub-layer 41 formed in FIG. 8 also covers a part of the first reference sub-electrode and a part of the second reference sub-electrode, so as to ensure that the thickness of the second dielectric sub-layer 42 formed in the first groove part and the second groove part is uniform.

S24, forming the second dielectric sub-layer 42 on a side of the first dielectric sub-layer 41 away from the dielectric substrate 10, where the second dielectric sub-layer 42 includes the first filling structure 421 filling the first groove part and the second filling structure 422 filling the second groove part.

In some examples, a material of the second dielectric sub-layer 42 includes, but is not limited to, resin adhesive. Taking the second dielectric sub-layer 42 made of resin adhesive as an example, step S24 may include: firstly, forming a filling material in both of the first groove part and the second groove part through a spin process, where an orthographic projection of the filling material on the dielectric substrate 10 covers orthographic projections of the first gap Q1 and the second gap Q2 on the dielectric substrate 10; and then heating the filling material, so that the filling material is reshaped to fill the first gap Q1 and the second gap Q2, to form the first filling structure 421 filling the first groove part and the second filling structure 422 filling the second groove part.

It should be noted that, the thicknesses of the first filling structure 421 and the second filling structure 422 are the same as the thickness of the driving electrode 30, and the control on the thickness of the first filling structure 421 and the second filling structure 422 can be realized by controlling the spin rate of the spin coating.

S25, forming a sacrificial layer 60 on a side of the first dielectric sub-layer 41 and the second dielectric sub-layer 42 away from the dielectric substrate 10.

In some examples, the sacrificial layer 60 may be made of silicon nitride, which is used because the first dielectric sub-layer 41 made of silicon oxide will not be damaged when the sacrificial layer 60 is removed subsequently. In a case where the sacrificial layer 60 is made of silicon nitride, the step S25 may include: forming the sacrificial layer 60 on the side of the first dielectric sub-layer 41 and the second dielectric sub-layer 42 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S26, forming the second dielectric layer 70 on a side of the sacrificial layer 60 away from the dielectric substrate 10.

In some examples, the second dielectric layer 70 may be made of silicon oxide. In a case where the first dielectric sub-layer 41 is made of silicon oxide, the step S26 may include: forming the second dielectric layer 70 on the side of the sacrificial layer 60 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S27, forming the membrane bridge on a side of the second dielectric layer 70 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10.

In some examples, two connecting arms 22 of the membrane bridge are in contact with and electrically connected to first reference electrode 51 and second reference electrode 52, respectively. Step S27 may specifically include: forming a second conductive film through, including but not limited to, magnetron sputtering, and then forming a pattern including the membrane bridge, through coating a photoresist, exposing and developing the photoresist, and etching (for example, wet etching), and finally removing the photoresist, to complete the manufacturing of the membrane bridge.

S28, removing the sacrificial layer 60.

In some examples, step S28 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge, to complete the manufacturing of the MEMS device. The gas atmosphere is SF₆ gas.

A third example is as follows. FIG. 10 is a schematic diagram illustrating a structure of a MEMS device in a second example of an embodiment of the present disclosure; as shown in FIG. 10, the MEMS device includes: a dielectric substrate 10; and a driving electrode 30, a first reference electrode 51, a second reference electrode 52, a first dielectric layer 40, a second dielectric layer 70, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10. The second dielectric layer 70 is located on a surface of a bridge deck 21 of the membrane bridge close to the dielectric substrate 10, and an orthographic projection of the second dielectric layer 70 on the dielectric substrate 10 covers at least an orthographic projection of the first dielectric layer 40 on the dielectric substrate 10. The second dielectric layer 70 has a first convex part 71 protruding toward the dielectric substrate 10. With the first convex part 71, the membrane bridge can be effectively prevented from being unable to bounce after being pulled down, so that reliability and reusability of the MEMS device are guaranteed, and device performance is improved.

In some examples, with continued reference to FIG. 10, the bridge deck 21 of the membrane bridge has a second convex part 211 protruding toward the first dielectric layer 40, the second convex part 211 is arranged in one-to-one correspondence with the first convex part 71, and the second convex part 211 is embedded in first convex part 71 corresponding to the second convex part 211. In this case, it can be ensured that the bridge deck 21 of the membrane bridge can be stably attached to the second dielectric layer 70.

Furthermore, a material of the first dielectric layer 40 and the second dielectric layer 70 may be silicon oxide.

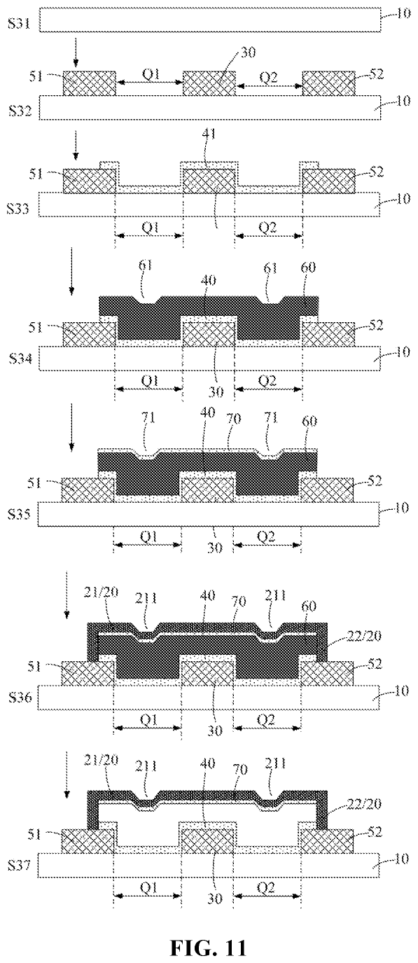

Next, a method of manufacturing a third exemplary MEMS device will be described. FIG. 11 is a flowchart of manufacturing the MEMS device shown in FIG. 10. As shown in FIG. 11, the manufacturing method may specifically include the following steps S31 to S37.

S31, providing the dielectric substrate 10.

In some examples, the dielectric substrate 10 may be a glass substrate, and in step S31, a glass substrate of 0.5 mm may be selected, and then the glass substrate is cleaned by a standard cleaning process.

S32, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S32 may include: forming a first conductive film through, including but not limited to, magnetron sputtering, and then forming the driving electrode 30, the first reference electrode 51 and the second reference electrode 52, through coating a photoresist, exposing and developing the photoresist, and etching (for example, wet etching), and finally, removing the remaining photoresist to complete the manufacturing of the driving electrode 30, the first reference electrode 51 and the second reference electrode 52.

S33, forming the first dielectric layer 40 on a side of a layer, where the driving electrode 30, the first reference electrode 51 and the second reference electrode 52 are located, away from the dielectric substrate 10; where the first dielectric layer 40 covers the driving electrode 30, and may further cover the first gap Q1 and the second gap Q2. In this case, the first dielectric layer 40 forms the first groove part and the second groove part located at the first gap Q1 and the second gap Q2, respectively.

In some examples, the first dielectric layer 40 may be made of silicon oxide. In a case where the first dielectric layer 40 is made of silicon oxide, the step S33 may include: forming the first dielectric layer 40 on the side of the layer, where the driving electrode 30, the first reference electrode 51 and the second reference electrode 52 are located, away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that, the first dielectric layer 40 formed in FIG. 10 also covers a part of the first reference sub-electrode and a part of the second reference sub-electrode.

S34, forming a sacrificial layer 60 on a side of the first dielectric layer 40 away from the dielectric substrate 10. In this case, the first dielectric layer 40 is formed to have the first groove part and the second groove part due to the presence of the first gap Q1 and the second gap Q2, and a surface of the sacrificial layer 60 away from the dielectric substrate 10 is formed to have a second concave part 61. Two second groove parts 61 are formed, and the two second groove parts correspond to the first concave part and the second concave part, respectively.

In some examples, the sacrificial layer 60 may be made of silicon nitride, which is used because the first dielectric layer 40 made of silicon oxide will not be damaged when the sacrificial layer 60 is removed subsequently. In a case where the sacrificial layer 60 is made of silicon nitride, the step S34 may include forming the sacrificial layer 60 on the side of the first dielectric layer 40 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S35, forming the second dielectric layer 70 on a side of the sacrificial layer 60 away from the dielectric substrate 10, where the sacrificial layer 60 has the second concave part 61, the second dielectric layer 70 thus formed has the first convex part 71 protruding toward the dielectric substrate 10, the first convex parts 71 and the second concave parts 61 are arranged corresponding to each other, and each first convex part 71 in embedded in one second concave part 61.

In some examples, the second dielectric layer 70 may be made of silicon oxide. In a case where the first dielectric sub-layer 41 is made of silicon oxide, the step S35 may include forming the second dielectric layer 70 on the side of the sacrificial layer 60 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S36, forming the membrane bridge on a side of the second dielectric layer 70 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10. Since the second dielectric layer 70 has the first convex part 71, the bridge deck 21 of the membrane bridge has the second convex part 211 protruding toward the first dielectric layer 40, the second convex part 211 is arranged in one-to-one correspondence with the first convex part 71, and the second convex part 211 is embedded in the first convex part 71 corresponding to the second convex part 211.

In some examples, two connecting arms 22 of the membrane bridge are in contact with and electrically connected to first reference electrode 51 and second reference electrode 52, respectively. Step S36 may specifically include: forming a second conductive film through, including but not limited to, magnetron sputtering, and then forming a pattern including the membrane bridge, through coating a photoresist, exposing and developing the photoresist, and etching (for example, wet etching), and finally removing the photoresist to complete the manufacturing of the membrane bridge.

S37, removing the sacrificial layer 60.

In some examples, step S37 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge, to complete the manufacturing of the MEMS device. The gas atmosphere is SF₆ gas.

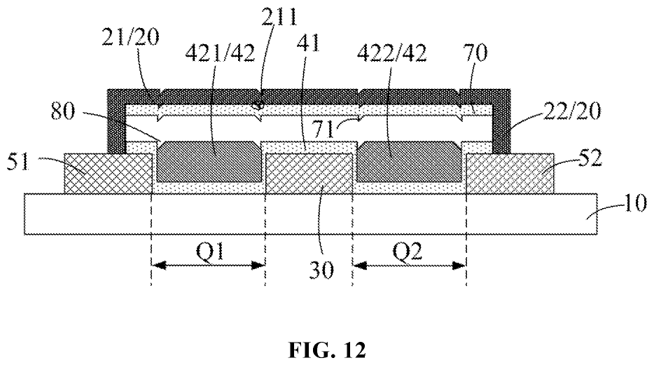

A fourth example is as follows. FIG. 12 is a schematic diagram illustrating a structure of a MEMS device in a second example of an embodiment of the present disclosure; as shown in FIG. 12, the MEMS device includes: a dielectric substrate 10; and a driving electrode 30, a first reference electrode 51, a second reference electrode 52, a first dielectric layer 40, a second dielectric layer 70, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The first dielectric sub-layer 41 covers the driving electrode 30 on a side of the driving electrode 30 away from the dielectric substrate 10. The second dielectric sub-layer 42 includes a first filling structure 421 and a second filling structure 422, and the first filling structure 421 and the second filling structure 422 fill the first gap Q1 and the second gap Q2, respectively. The first filling structure 421 and the second filling structure 422 each have a first face in contact with the first dielectric sub-layer 41, a second face arranged opposite to the dielectric substrate 10, and a first connection face connecting the first face and the second face. The first connection face and the first dielectric sub-layer 41 define a first concave part 80. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10. The second dielectric layer 70 is located on a surface of a bridge deck 21 of the membrane bridge close to the dielectric substrate 10, and an orthographic projection of the second dielectric layer 70 on the dielectric substrate 10 covers at least an orthographic projection of the first dielectric layer 40 on the dielectric substrate 10. The second dielectric layer 70 has a first convex part 71 protruding toward the dielectric substrate 10, and the first convex part 71 is arranged in one-to-one correspondence with the first concave part 80. With the first convex part 71, the membrane bridge can be effectively prevented from being unable to bounce after being pulled down, so that reliability and reusability of the MEMS device are guaranteed, and device performance is improved.

In some examples, with continued reference to FIG. 12, the bridge deck 21 of the membrane bridge has a second convex part 211 protruding toward the first dielectric layer 40, the second convex part 211 is arranged in one-to-one correspondence with the first convex part 71, and the second convex part 211 is embedded in the first convex part 71 corresponding to the second convex part 211. In this case, it can be ensured that the bridge deck 21 of the membrane bridge can be stably attached to the second dielectric layer 70.

Furthermore, a material of each of the first dielectric sub-layer 41 and the second dielectric sub-layer 70 may be silicon oxide. A material of each of the second dielectric sub-layer 42, that is, a material of the first filling structure 421 and the second filling structure 422, may be resin adhesive.

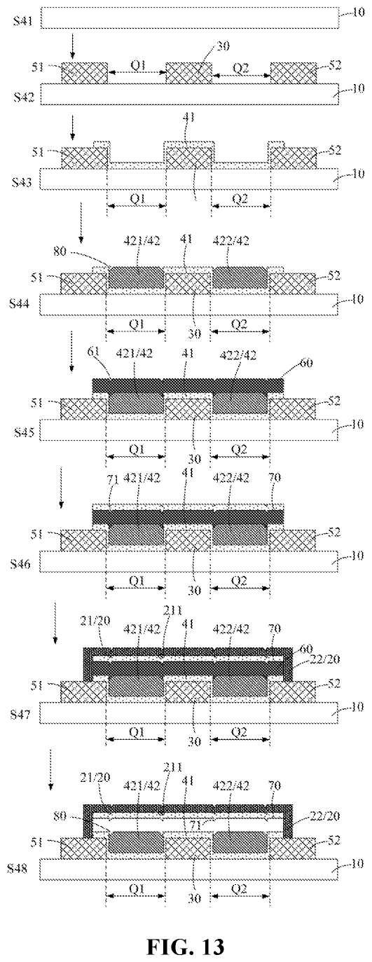

Next, a method of manufacturing a fourth exemplary MEMS device will be described. FIG. 13 is a flowchart of manufacturing the MEMS device shown in FIG. 12. As shown in FIG. 13, the manufacturing method may specifically include the following steps S41 to S48.

S41, providing the dielectric substrate 10.

In some examples, the dielectric substrate 10 may be a glass substrate, and in step S31, a glass substrate of 0.5 mm may be selected, and then the glass substrate is cleaned through a standard cleaning process.

S42, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S42 may include: forming a first conductive film through, including but not limited to, magnetron sputtering, and then forming the driving electrode 30, the first reference electrode 51 and the second reference electrode 52, through coating a photoresist, exposing and developing the photoresist, and etching (for example, wet etching), and finally, removing the remaining photoresist to complete the manufacturing of the driving electrode 30, the first reference electrode 51 and the second reference electrode 52.

S43, forming the first dielectric sub-layer 41 on a side of a layer, where the driving electrode 30, the first reference electrode 51 and the second reference electrode 52 are located, away from the dielectric substrate 10; where the first dielectric sub-layer 41 covers the driving electrode 30, and may further cover the first gap Q1 and the second gap Q2. In this case, the first sub dielectric layer 41 forms the first groove part and the second groove part located at the first gap Q1 and the second gap Q2, respectively.

In some examples, the first dielectric sub-layer 41 may be made of silicon oxide. In a case where the first dielectric sub-layer 41 is made of silicon oxide, the step S43 may include: forming the first dielectric sub-layer 41 of the first dielectric layer 40 on the side of the layer, where the driving electrode 30, the first reference electrode 51 and the second reference electrode 52 are located, away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that, the first dielectric sub-layer 41 formed in FIG. 12 also covers a part of the first reference sub-electrode and a part of the second reference sub-electrode.

S44, forming the second dielectric sub-layer 42 on a side of the first dielectric sub-layer 41 away from the dielectric substrate 10, where the second dielectric sub-layer 42 includes the first filling structure 421 filling the first groove part and the second filling structure 422 filling the second groove part. The first filling structure 421 and the second filling structure 422 each are formed to have the first surface in contact with the first dielectric sub-layer 41, the second surface opposite to the dielectric substrate 10, and the first connection face connecting the first surface and the second surface. The first connection face and the first dielectric sub-layer 41 define the first concave part 80.

In some examples, a material of the second dielectric sub-layer 42 includes, but is not limited to, resin adhesive. Taking the second dielectric sub-layer 42 made of resin adhesive as an example, step S44 may include: firstly, forming a filling material in both of the first groove part and the second groove part through a spin process, where an orthographic projection of the filling material on the dielectric substrate 10 covers orthographic projections of the first gap Q1 and the second gap Q2 on the dielectric substrate 10; and then through annealing, the filling material is reshaped to fill the first gap Q1 and the second gap Q2, to form the first filling structure 421 filling the first groove part and the second filling structure 422 filling the second groove part, where the first filling structure 421 and the second filling structure 422 thus formed each have the first surface in contact with the first dielectric sub-layer 41, the second surface arranged opposite to the dielectric substrate 10, and the first connection face connecting the first surface and the second surface; and the first connection face and the first dielectric sub-layer 41 define the first concave part 80.

It should be noted that, the thicknesses of the first filling structure 421 and the second filling structure 422 are the same as the thickness of the driving electrode 30, and the control on the thickness of the first filling structure 421 and the second filling structure 422 can be realized by controlling the spin rate of the spin coating.

S45, forming a sacrificial layer 60 on a side of the first dielectric layer 40 away from the dielectric substrate 10. In this case, since the first concave part 80 is formed between the second dielectric sub-layer 42 and the first dielectric sub-layer 41, a surface of the sacrificial layer 60 away from the dielectric substrate 10 is formed to have the second concave part 61. The second concave part 61 is arranged in one-to-one correspondence with the first concave part 80, and the second concave part 61 is embedded in the first concave part 80 corresponding to the second concave part 61.

In some examples, the sacrificial layer 60 may be made of silicon nitride, which is used because the first dielectric layer 40 made of silicon oxide will not be damaged when the sacrificial layer 60 is removed subsequently. In a case where the sacrificial layer 60 is made of silicon nitride, the step S45 may include forming the sacrificial layer 60 on the side of the first dielectric layer 40 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S46, forming the second dielectric layer 70 on a side of the sacrificial layer 60 away from the dielectric substrate 10, where the sacrificial layer 60 has the second concave part 61, the second dielectric layer 70 thus formed has the first convex part 71 protruding toward the dielectric substrate 10, the first convex part 71 and the second concave part 61 are arranged corresponding to each other, and each first convex part 71 is embedded in one second concave part 61.

In some examples, the second dielectric layer 70 may be made of silicon oxide. In a case where the first dielectric sub-layer 41 is made of silicon oxide, the step S46 may include forming the second dielectric layer 70 on the side of the sacrificial layer 60 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S47, forming the membrane bridge on a side of the second dielectric layer 70 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10. Since the second dielectric layer 70 has the first convex part 71, the bridge deck 21 of the membrane bridge has the second convex part 211 protruding toward the first dielectric layer 40, the second convex part 211 is arranged in one-to-one correspondence with the first convex part 71, and the second convex part 211 is embedded in the first convex part 71 corresponding to the second convex part 211.

In some examples, two connecting arms 22 of the membrane bridge are in contact with and electrically connected to first reference electrode 51 and second reference electrode 52, respectively. Step S47 may specifically include: forming a second conductive film through, including but not limited to, magnetron sputtering, and then forming a pattern including the membrane bridge, through coating a photoresist, exposing and developing the photoresist, and etching (for example, wet etching), and finally removing the photoresist to complete the manufacturing of the membrane bridge.

S48, removing the sacrificial layer 60.

In some examples, step S48 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge to complete the manufacturing of the MEMS device. The gas atmosphere is SF₆ gas.

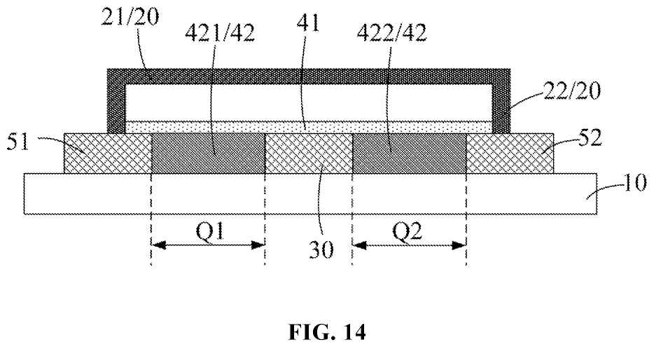

A fifth example is as follows. FIG. 14 is a schematic diagram illustrating a structure of a MEMS device in a second example of an embodiment of the present disclosure; as shown in FIG. 14, the MEMS device includes: a dielectric substrate 10; and a driving electrode 30, a first reference electrode 51, a second reference electrode 52, a first dielectric layer 40, and a membrane bridge arranged on the dielectric substrate 10. The first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30. The first dielectric layer 40 includes a second dielectric sub-layer 42 and a first dielectric sub-layer 41 sequentially arranged along a direction away from the dielectric substrate 10. The first dielectric sub-layer 41 covers the second dielectric layer 70 on a side of the second dielectric layer 70 away from the dielectric substrate 10. The second dielectric sub-layer 42 includes a first filling structure 421 and a second filling structure 422, and the first filling structure 421 and the second filling structure 422 fill the first gap Q1 and the second gap Q2, respectively. The membrane bridge is arranged on a side of the first dielectric layer 40 away from the dielectric substrate 10, and two ends of an orthographic projection of the membrane bridge on the dielectric substrate 10 overlap orthographic projections of the first reference electrode 51 and the second reference electrode 52 on the dielectric substrate 10, respectively. The driving electrode 30 is located in the space enclosed by the membrane bridge and the dielectric substrate 10.

In some examples, with continued reference to FIG. 14, in order to ensure that a surface of the first dielectric sub-layer 41 away from the dielectric substrate 10 is flat, a thickness of each of the first filling structure 421 and the second filling structure 422 is the same as a thickness of the driving electrode 30.

Furthermore, a material of each of the first dielectric sub-layer 41 may be silicon oxide. A material of the second dielectric sub-layer 42, that is, a material of each of the first filling structure 421 and the second filling structure 422, may be resin adhesive.

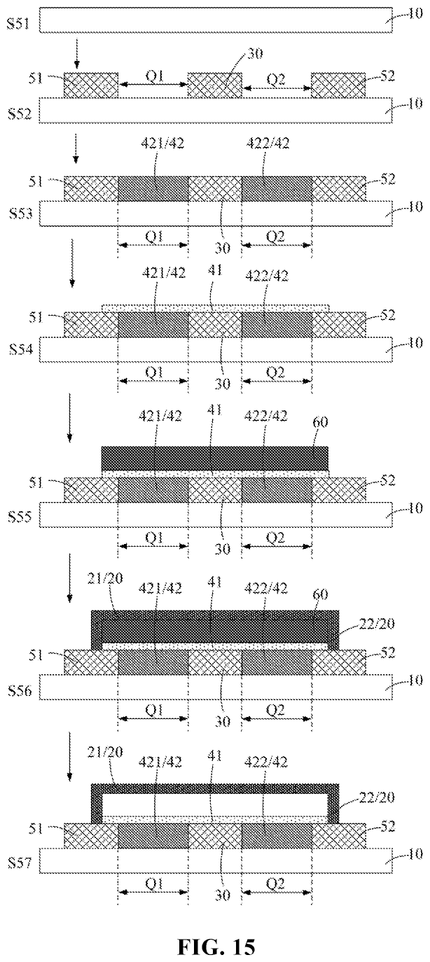

Next, a method of manufacturing a fifth exemplary MEMS device will be described. FIG. 15 is a flowchart of manufacturing the MEMS device shown in FIG. 14. As shown in FIG. 15, the manufacturing method may specifically include the following steps S51 to S57.

S51, providing the dielectric substrate 10.

In some examples, the dielectric substrate 10 may be a glass substrate, and in step S51, a glass substrate of 0.5 mm may be selected, and then the glass substrate is cleaned through a standard cleaning process.

S52, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S52 may include: forming a first conductive film through, including but not limited to, magnetron sputtering, and then forming the driving electrode 30, the first reference electrode 51 and the second reference electrode 52, through coating a photoresist, exposing and developing the photoresist, and etching (for example, wet etching), and finally, removing the remaining photoresist to complete the manufacturing of the driving electrode 30, the first reference electrode 51 and the second reference electrode 52.

S53, forming the second dielectric sub-layer 42 of the first dielectric layer 40 on a side of a layer, where the driving electrode 30, the first reference electrode 51 and the second reference electrode 52 are located, away from the dielectric substrate 10, where the second dielectric sub-layer 42 includes the first filling structure 421 filling the first gap Q1 and the second filling structure 422 filling the second gap Q2.

In some examples, a material of the second dielectric sub-layer 42 includes, but is not limited to, resin adhesive. Taking the second dielectric sub-layer 42 made of resin adhesive as an example, step S53 may include: firstly, forming a filling material in both of the first gap Q1 and the second gap Q2 through a spin process, where an orthographic projection of the filling material on the dielectric substrate 10 covers orthographic projections of the first gap Q1 and the second gap Q2 on the dielectric substrate 10; and then heating the filling material, so that the filling material is reshaped to fill the first gap Q1 and the second gap Q2, to form the first filling structure 421 filling the first gap Q1 and the second filling structure 422 filling the second gap Q2.

It should be noted that, the thicknesses of the first filling structure 421 and the second filling structure 422 are the same as the thickness of the driving electrode 30, and the control on the thickness of the first filling structure 421 and the second filling structure 422 can be realized by controlling the spin rate of the spin coating.

S54, forming the first dielectric sub-layer 41 on a side of the first dielectric sub-layer 41 away from the dielectric substrate 10; where the first dielectric sub-layer 41 covers the second dielectric sub-layer 42, and may further cover the driving electrode 30.

In some examples, the first dielectric sub-layer 41 may be made of silicon oxide. In a case where the first dielectric sub-layer 41 is made of silicon oxide, the step S54 may include forming the first dielectric sub-layer 41 of the first dielectric layer 40 on the side of the second dielectric sub-layer 42 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that the first dielectric sub-layer 41 formed in FIG. 14 also covers a part of the first reference sub-electrode and a part of the second reference sub-electrode, so as to ensure that the thickness of the second dielectric sub-layer 42 formed in the first groove part and the second groove part is uniform.

S55, forming a sacrificial layer 60 on a side of the first dielectric sub-layer 41 and the second dielectric sub-layer 42 away from the dielectric substrate 10.

In some examples, the sacrificial layer 60 may be made of silicon nitride, which is used because the first dielectric sub-layer 41 made of silicon oxide will not be damaged when the sacrificial layer 60 is removed subsequently. In a case where the sacrificial layer 60 is made of silicon nitride, the step S55 may include forming the sacrificial layer 60 on the side of the first dielectric sub-layer 41 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S56, forming the membrane bridge on a side of the sacrificial layer 60 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10.

In some examples, two connecting arms 22 of the membrane bridge are in contact with and electrically connected to first reference electrode 51 and second reference electrode 52, respectively. Step S56 may specifically include: forming a second conductive film through, including but not limited to, magnetron sputtering, and then forming a pattern including the membrane bridge, through coating a photoresist, exposing and developing the photoresist, and etching (for example, wet etching), and finally removing the photoresist to complete the manufacturing of the membrane bridge.

S57, removing the sacrificial layer 60.

In some examples, step S57 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge, to complete the manufacturing of the MEMS device. The gas atmosphere is SF₆ gas.

In some examples, it is taken as an example that the sacrificial layer 60 is made of silicon nitride, the material of the sacrificial layer 60 may alternatively be photoresist, and in this case, the corresponding first dielectric layer 40 may be a composite film of silicon nitride/silicon oxide. In the case where the sacrificial layer 60 is made of photoresist, a wet etching process may be subsequently used to remove the sacrificial layer 60.

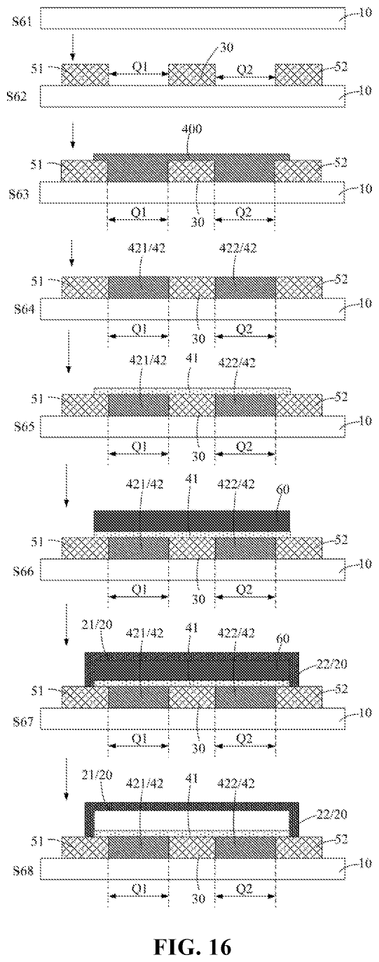

For the fifth exemplary MEMS device, an embodiment of the present disclosure further provides another method of manufacturing the MEMS device. FIG. 16 is a flowchart of manufacturing the MEMS device shown in FIG. 14; as shown in FIG. 16, the manufacturing method includes the following steps S61 to S68.

S61, providing the dielectric substrate 10.

In some examples, the dielectric substrate 10 may be a glass substrate, and in step S61, a glass substrate of 0.5 mm may be selected, and then the glass substrate is cleaned through a standard cleaning process.

S62, forming the driving electrode 30, the first reference electrode 51 and the second reference electrode 52 on the dielectric substrate 10; where the first reference electrode 51 and the second reference electrode 52 are respectively located on two sides of the driving electrode 30 in the extending direction of the driving electrode 30, a first gap Q1 is formed between the first reference electrode 51 and the driving electrode 30, and a second gap Q2 is formed between the second reference electrode 52 and the driving electrode 30.

In some examples, step S62 may include: forming a first conductive film through, including but not limited to, magnetron sputtering, and then forming the driving electrode 30, the first reference electrode 51 and the second reference electrode 52, through coating a photoresist, exposing and developing the photoresist, and etching (for example, wet etching), and finally, removing the remaining photoresist to complete the manufacturing of the driving electrode 30, the first reference electrode 51 and the second reference electrode 52.

S63, forming a filling material on a side of a layer, where the driving electrode 30, the first reference electrode 51 and the second reference electrode 52 are located, away from the dielectric substrate 10, where the second dielectric sub-layer 42 covers the first gap Q1, the second gap Q2, and the driving electrode 30.

In some examples, the filling material includes, but is not limited to, resin adhesive. Taking the second dielectric sub-layer 42 made of resin adhesive as an example, step S53 may include: firstly, forming the filling material in the first gap Q1 and the second gap Q2 and on the driving electrode 30, through a spin process.

S64, removing the filling material above the driving electrode 30, and leaving only the first filling structure 421 filling the first gap Q1 and the second filling structure 422 filling the second gap Q2, to form the second dielectric sub-layer 42 of the first dielectric layer 40; where a thickness of the first filling structure 421 and the second filling structure 422 is the same as a thickness of the driving electrode 30.

In some examples, step S64 may include polishing the filling material above the driving electrode 30 through Chemical Mechanical Polishing (CMP), leaving only the first filling structure 421 filling the first gap Q1 and the second filling structure 422 filling the second gap Q2, to form the second dielectric sub-layer 42 of the first dielectric layer 40; where the thickness of each of the first filling structure 421 and the second filling structure 422 is the same as the thickness of the driving electrode 30.

S65, forming the first dielectric sub-layer 41 on a side of the first dielectric sub-layer 41 away from the dielectric substrate 10; where the first dielectric sub-layer 41 covers the second dielectric sub-layer 42, and may further cover the driving electrode 30.

In some examples, the first dielectric sub-layer 41 may be made of silicon oxide. In a case where the first dielectric sub-layer 41 is made of silicon oxide, the step S65 may include forming the first dielectric sub-layer 41 of the first dielectric layer 40 on the side of the second dielectric sub-layer 42 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

It should be noted that the first dielectric sub-layer 41 formed in FIG. 14 also covers a part of the first reference sub-electrode and a part of the second reference sub-electrode, so as to ensure that the thickness of the second dielectric sub-layer 42 formed in the first groove part and the second groove part is uniform.

S66, forming the sacrificial layer 60 on a side of the first dielectric sub-layer 41 and the second dielectric sub-layer 42 away from the dielectric substrate 10.

In some examples, the sacrificial layer 60 may be made of silicon nitride, which is used because the first dielectric sub-layer 41 made of silicon oxide will not be damaged when the sacrificial layer 60 is removed subsequently. In a case where the sacrificial layer 60 is made of silicon nitride, the step S66 may include forming the sacrificial layer 60 on the side of the first dielectric sub-layer 41 away from the dielectric substrate 10, through a plasma enhanced chemical vapor deposition method, a low pressure chemical vapor deposition method, an atmospheric pressure chemical vapor deposition method, or an electron cyclotron resonance chemical vapor deposition or sputtering method.

S67, forming the membrane bridge on a side of the sacrificial layer 60 away from the dielectric substrate 10, where two ends of an orthographic projection of the membrane bridge on the dielectric substrate 10 overlap orthographic projections of the first reference electrode 51 and the second reference electrode 52 on the dielectric substrate 10, respectively; and the driving electrode 30 is located in the space enclosed by the membrane bridge and the dielectric substrate 10.

In some examples, two connecting arms 22 of the membrane bridge are in contact with and electrically connected to first reference electrode 51 and second reference electrode 52, respectively. Step S67 may specifically include: forming a second conductive film through, including but not limited to, magnetron sputtering, and then forming a pattern including the membrane bridge, through coating a photoresist, exposing and developing the photoresist, and etching (for example, wet etching), and finally removing the photoresist to complete the manufacturing of the membrane bridge.

S68, removing the sacrificial layer 60.

In some examples, step S68 may include performing a precisely controlled etching on the sacrificial layer 60 under the membrane bridge, through adopting Reactive Ion Etching (RIE), reasonably controlling gas atmosphere (lateral etching strength), pressure, power (etching rate), etching time, and the like, to remove the sacrificial layer 60 under the membrane bridge, to complete the manufacturing of the MEMS device. The gas atmosphere is SF₆ gas.

An embodiment of the present disclosure provides an electronic apparatus, which includes any one of the MEMS devices described above. The electronic apparatus includes, but is not limited to, a phase shifter.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without away from the spirit and essence of the present disclosure, and such modifications and improvements are also considered to be within the scope of the present disclosure.

1. A MEMS device, comprising:
a dielectric substrate;
a driving electrode, a first reference electrode and a second reference electrode on the dielectric substrate, wherein the first reference electrode and the second reference electrode are on two sides of the driving electrode in an extending direction of the driving electrode, respectively;
a first dielectric layer covering the driving electrode on a side of the driving electrode away from the dielectric substrate; and
a membrane bridge on a side of the first dielectric layer away from the dielectric substrate, wherein two ends of an orthographic projection of the membrane bridge on the dielectric substrate overlap orthographic projections of the first reference electrode and the second reference electrode on the dielectric substrate, respectively; and the driving electrode is in a space enclosed by the membrane bridge and the dielectric substrate,
wherein a first gap is between the first reference electrode and the driving electrode; a second gap is between the second reference electrode and the driving electrode; and
a thickness of a part of the first dielectric layer at each of the first gap and the second gap is greater than a thickness of the driving electrode; and/or, a second dielectric layer is on a side of a bridge deck of the membrane bridge close to the dielectric substrate, and an orthographic projection of the second dielectric layer on the dielectric substrate covers at least an orthographic projection of the driving electrode on the dielectric substrate.

2. The MEMS device according to claim 1, wherein the thickness of the part of the first dielectric layer at each of the first gap and the second gap is greater than the thickness of the driving electrode, the first dielectric layer comprises a first dielectric sub-layer and a second dielectric sub-layer sequentially arranged along a direction away from the dielectric substrate; and
the second dielectric sub-layer comprises a first filling structure and a second filling structure; and the first filling structure and the second filling structure are in the first gap and the second gap, respectively.

3. The MEMS device according to claim 2, wherein the first dielectric sub-layer covers the first gap and the second gap, the first dielectric sub-layer forms a first groove part at the first gap, and forms a second groove part at the second gap; the first filling structure fills the first groove part, and the second filling structure fills the second groove part.

4. The MEMS device according to claim 2, wherein a material of the second dielectric sub-layer comprises resin adhesive.

5. The MEMS device according to claim 1, wherein the second dielectric layer is on the side of the bridge deck of the membrane bridge close to the dielectric substrate, and the second dielectric layer has a first convex part protruding toward the first dielectric layer.

6. The MEMS device according to claim 5, wherein the bridge deck of the membrane bridge has a second convex part protruding toward the first dielectric layer, the second convex part is in one-to-one correspondence with the first convex part, and the second convex part is embedded in the first convex part corresponding to the second convex part.

7. The MEMS device according to claim 5, wherein the thickness of the part of the first dielectric layer at each of the first gap and the second gap is greater than the thickness of the driving electrode, a surface of the first dielectric layer close to the second dielectric layer has a first concave part; and the first concave part and the first convex part are in one-to-one correspondence.

8. The MEMS device according to claim 7, wherein the first dielectric layer comprises a first dielectric sub-layer and a second dielectric sub-layer sequentially arranged along a direction away from the dielectric substrate; and
the second dielectric sub-layer comprises a first filling structure and a second filling structure; and the first filling structure and the second filling structure are in the first gap and the second gap, respectively.

9. The MEMS device according to claim 8, wherein the first filling structure and the second filling structure each have a first face in contact with the first sub-dielectric layer, a second face opposite to the dielectric substrate, and a first connection face connecting the first face and the second face; and the first connection face and the first dielectric sub-layer define the first concave part.

10. The MEMS device according to claim 8, wherein a material of the second dielectric sub-layer comprises resin adhesive.

11. The MEMS device according to claim 1, wherein the thickness of the part of the first dielectric layer at each of the first gap and the second gap is greater than the thickness of the driving electrode, and the first dielectric layer comprises a first dielectric sub-layer and a second dielectric sub-layer sequentially arranged along a direction close to the dielectric substrate; and
the second dielectric sub-layer comprises a first filling structure and a second filling structure; and the first filling structure and the second filling structure are in the first gap and the second gap, respectively.

12. The MEMS device according to claim 11, wherein a material of the second dielectric sub-layer comprises resin adhesive.

13. A method of manufacturing a MEMS device, comprising:
providing a dielectric substrate;
forming a driving electrode, a first reference electrode and a second reference electrode on the dielectric substrate; wherein the first reference electrode and the second reference electrode are on two sides of the driving electrode in an extending direction of the driving electrode, respectively;
forming a first dielectric layer on a side of the driving electrode, the first reference electrode and the second reference electrode, away from the dielectric substrate; and
forming a membrane bridge on a side of the first dielectric layer away from the dielectric substrate, wherein two ends of an orthographic projection of the membrane bridge on the dielectric substrate overlap orthographic projections of the first reference electrode and the second reference electrode on the dielectric substrate, respectively; and the driving electrode is in a space enclosed by the membrane bridge and the dielectric substrate,
wherein a first gap is between the first reference electrode and the driving electrode; a second gap is between the second reference electrode and the driving electrode; and a thickness of a part of the first dielectric layer at each of the first gap and the second gap is greater than a thickness of the driving electrode; and/or
the method further comprises forming a second dielectric layer on a side of a bridge deck of the membrane bridge close to the dielectric substrate, wherein an orthographic projection of the second dielectric layer on the dielectric substrate covers at least an orthographic projection of the driving electrode on the dielectric substrate.

14. The method according to claim 13, wherein the thickness of the part of the first dielectric layer at each of the first gap and the second gap is greater than the thickness of the driving electrode, and forming the first dielectric layer comprises:
sequentially forming a first dielectric sub-layer and a second dielectric sub-layer along a direction away from the dielectric substrate; wherein the second dielectric sub-layer comprises a first filling structure and a second filling structure; and the first filling structure and the second filling structure are in the first gap and the second gap, respectively.

15. The method according to claim 13, wherein the method comprises providing the second dielectric layer on the side of the bridge deck of the membrane bridge close to the dielectric substrate, and before forming the second dielectric layer, the method further comprises:
forming a sacrificial layer on a surface of the first dielectric layer away from the dielectric substrate, wherein the sacrificial layer has a second concave part on a side of the sacrificial layer away from the dielectric substrate; and
the second dielectric layer is formed on a side of the sacrificial layer away from the dielectric substrate, and the second dielectric layer has a first convex part protruding toward the dielectric substrate; and the first convex part and the second concave part are arranged in one-to-one correspondence; and
the method further comprises removing the sacrificial layer after forming the membrane bridge.

16. The method u according to claim 13, wherein the thickness of the part of the first dielectric layer at each of the first gap and the second gap is greater than the thickness of the driving electrode, and the method comprises providing the second dielectric layer at the side of the bridge deck of the membrane bridge close to the dielectric substrate,
forming the first dielectric layer comprises:
sequentially forming a first dielectric sub-layer and a second dielectric sub-layer along a direction away from the dielectric substrate; wherein the second dielectric sub-layer comprises a first filling structure and a second filling structure; and the first filling structure and the second filling structure are in the first gap and the second gap, respectively;
forming the second dielectric sub-layer comprises:
forming a filling material in the first gap and the second gap, and annealing to form the first filling structure and the second filling structure; wherein the first filling structure and the second filling structure each have a first face in contact with the first sub-dielectric layer, a second face opposite to the dielectric substrate, and a first connection face connecting the first surface and the second face; and the first connection face and the first dielectric sub-layer define the first concave part;
after forming the second dielectric sub-layer, the method further comprises:
forming a sacrificial layer on a surface of the first dielectric layer away from the dielectric substrate; wherein the sacrificial layer has a second concave part on a side of the sacrificial layer away from the dielectric substrate; and the second concave part and the first concave part are arranged in one-to-one correspondence; and
the second dielectric layer is formed on a side of the sacrificial layer away from the dielectric substrate, and the second dielectric layer has a first convex part protruding toward the dielectric substrate; and the first convex part and the second concave part are arranged in one-to-one correspondence; and
the method further comprises removing the sacrificial layer after forming the membrane bridge.

17. The method g according to claim 16, wherein the bridge deck of the membrane bridge is formed to have a second convex part protruding toward the first dielectric layer, and the second convex parts is arranged in one-to-one correspondence with the first convex part, and the second convex part is embedded in the first convex part corresponding to the second convex part.

18. The method according to claim 13, wherein the thickness of the part of the first dielectric layer at each of the first gap and the second gap is greater than the thickness of the driving electrode, and forming the first dielectric layer comprises:
sequentially forming a second dielectric sub-layer and a first dielectric sub-layer along a direction away from the dielectric substrate; wherein the second dielectric sub-layer comprises a first filling structure and a second filling structure; and the first filling structure and the second filling structure are in the first gap and the second gap, respectively;
forming the second dielectric sub-layer comprises:
forming a second dielectric material sub-layer, wherein the second dielectric material layer protrudes out of the first gap and the second gap; and
heating the second dielectric material sub-layer, such that the second dielectric material sub-layer is reshaped to fill the first gap and the second gap, to form the first filling structure and the second filling structure.

19. The method according to claim 13, wherein the thickness of the part of the first dielectric layer at each of the first gap and the second gap is greater than the thickness of the driving electrode, forming the first dielectric layer comprises:
sequentially forming a second dielectric sub-layer and a first dielectric sub-layer along a direction away from the dielectric substrate; the second dielectric sub-layer comprises a first filling structure and a second filling structure; and the first filling structure and the second filling structure are in the first gap and the second gap, respectively; and
forming the second dielectric sub-layer comprises:
forming a second dielectric material sub-layer, wherein the second dielectric material layer protrudes out of the first gap and the second gap; and
removing, through chemical mechanical polishing and grinding process, a part of the second dielectric material sub-layer protruding out of the first gap and the second gap, to form the first filling structure and the second filling structure filled in the first gap and the second gap, respectively.

20. An electronic apparatus, comprising the MEMS device according to claim 1.
